(19) United States
(12) Patent Application Publication
(10) Pub. No.: US 2012/0034550 A1
(43) Pub. Date: Feb. 9, 2012

(54) Palladium-Platinum Nanostructures And Methods For Their Preparation

(75) Inventors: Younan Xia, St. Louis, MO (US); Byungkwon Lim, St. Louis, MO (US); Majiong Jiang, St. Louis, MO (US)

(73) Assignee: WASHINGTON UNIVERSITY IN ST. LOUIS, St. Louis, MO (US)

(21) Appl. No.: 13/265,495

(22) PCT Filed: Apr. 20, 2010
(86) PCT No.: PCT/US10/31749

§ 371 Date: Oct. 20, 2011

Related U.S. Application Data
(60) Provisional application No. 61/171,255, filed on Apr. 21, 2009.

(51) Int. Cl. H01M 4/92; C30B 19/00; B32B 15/01

(52) U.S. Cl. 429/524; 428/670; 117/64; 117/58

(57) ABSTRACT

Palladium-seeded, dendritic platinum nanostructures that are useful as electrocatalysts and methods for preparing such nanostructures. The palladium-platinum nanostructures may be incorporated into fuel cell electrodes including fuel cells that include a proton exchange membrane (PEM).

### CROSS-REFERENCE TO RELATED APPLICATION

This application claims the benefit of U.S. Provisional Application No. 61/171,255, filed Apr. 21, 2009, which is incorporated by reference herein in its entirety.

### BACKGROUND

The field of the disclosure relates to palladium-platinum nanostructures and, more particularly, to palladium-seeded, dendritic platinum nanostructures that are useful as electrocatalysts. The palladium-platinum nanostructures of embodiments of the present disclosure may be incorporated into fuel cell electrodes including fuel cells that include a proton exchange membrane (PEM).

Researchers have increasingly focused on utilizing fuel cells for a variety of applications such as, for example, powering consumer electronics, effluent gas treatment, and transportation (e.g., cars and buses). Many different fuel cell designs are available including proton exchange membrane (PEM), direct methanol, phosphoric acid, solid oxide, molten carbonate, alkaline, zinc-air and microbial fuel cells.

PEM fuel cells may be utilized in automobile applications. It is believed that hydrogen-fueled PEM fuel cells may replace the combustion engine as the principal source of power generation in vehicles. PEM fuel cells use a solid polymer membrane as the electrolytic material for transporting protons. At the anode of the fuel cell, hydrogen molecules are split into protons and electrons. The electrons flow through an electrical circuit and produce electrical power while the protons pass through the proton exchange membrane. The protons combine with oxygen atoms and the electrons at the cathode to produce water, the only by-product of the fuel cell. The chemistry of the fuel cell is illustrated in the reactions below.

2H₂=>4H⁺+4e− (i) Anode Reaction:

O₂+4H⁺+4e−=>2H₂O (ii) Cathode Reaction:

2H₂+O₂=>2H₂O (iii) Overall Reaction:

Typically the cathode reaction is the rate-determining step in the fuel cell.

Electrode reactions are catalyzed by electrocatalysts such as platinum black and carbon-supported platinum. A need exists for platinum catalysts that exhibit improved catalytic properties in fuel cell applications and, particularly, which increase the activity of the oxygen reduction reaction that occurs at the fuel cell cathode. Platinum catalysts which are characterized by a relatively large surface area and a relatively large number of available active sites are specifically desired.

### SUMMARY

In one aspect of the present disclosure, a method of producing a palladium-platinum nanostructure comprises contacting palladium nanocrystals with a platinum-containing compound. The platinum-containing compound is reduced with a reducing agent to cause platinum to deposit on the palladium nanocrystal and form platinum nanodendritic branches.

Another aspect of the disclosure is directed to a palladium-platinum nanostructure. The nanostructure comprises a palladium nanocrystal and a nanodendritic branch extending from the palladium nanocrystal.

In a further aspect of the present disclosure, a fuel cell comprises a first electrode, a second electrode and an electrolyte between the first electrode and the second electrode. The first electrode comprises palladium-platinum nanostructures comprising palladium nanocrystals and platinum nanodendritic branches extending from the palladium nanocrystals.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a TEM image of truncated octahedral palladium nanocrystals prepared according to Example 1;

FIG. 2 is an HRTEM image of a palladium nanocrystal prepared according to Example 1;

FIG. 3 is an HRTEM image of a palladium nanocrystal prepared according to Example 1 with the crystal fringe orientation illustrated;

FIG. 4 is a chart illustrating the particle size distribution of palladium nanocrystals prepared according to Example 1;

FIG. 5 is a HAADF-STEM image of palladium-platinum nanostructures prepared according to Example 2;

FIG. 6 is a TEM image of palladium-platinum nanostructures prepared according to Example 2;

FIG. 7 is an HRTEM image of a palladium-platinum nanostructure prepared according to Example 2;

FIGS. 8-10 are EDS graphical analysis at three points of the nanostructure of FIG. 7;

FIG. 11 is an HRTEM image of a palladium-platinum nanostructure prepared according to Example 2;

FIG. 12 is an HRTEM image of the center of the nanostructure of FIG. 11;

FIGS. 13-16 are HRTEM images of several of the branches of the nanostructure of FIG. 11;

FIG. 17 is a TEM image of a platinum nanostructure prepared without use of a palladium nanocrystal;

FIG. 18 is a chart illustrating the particle size distribution of palladium-platinum nanostructures prepared according to Example 2;

FIG. 19 is a graphical illustration of cyclic voltammetry measurements of palladium-platinum nanostructures prepared in accordance with Example 2, carbon-supported platinum and platinum black;

FIG. 20 is a chart illustrating the specific electrochemically active surface area (ECSA) for palladium-platinum nanostructures prepared in accordance with Example 2 (on a palladium-platinum basis and platinum only basis), carbon-supported platinum and platinum black;

FIG. 21 is a TEM image of platinum black;

FIG. 22 is a graphical illustration of polarization curves of palladium-platinum nanostructures prepared in accordance with Example 2, carbon-supported platinum and platinum black for the oxygen reduction reaction at room temperature and at 60° C.;

FIG. 23 is a chart illustrating the mass activity toward the oxygen reduction reaction for palladium-platinum nanostructures prepared in accordance with Example 2 (on a palladium-platinum basis and platinum only basis), carbon-supported platinum and platinum black at room temperature and at 60° C.;

FIG. 24 is a chart illustrating the specific activity toward the oxygen reduction reaction normalized in reference to the ECSA for palladium-platinum nanostructures prepared in accordance with Example 2, carbon-supported platinum and platinum black at room temperature and at 60° C.;

FIG. 25 is a graphical illustration of cyclic voltammetry measurements of palladium-platinum nanostructures prepared in accordance with Example 2 after preparation, after 4000 cycles of accelerated durability test and after 10,000 cycles of accelerated durability test;

FIG. 26 is a graphical illustration of cyclic voltammetry measurements of carbon-supported platinum after preparation and after 4000 cycles of accelerated durability test; and

FIG. 27 is a graphical illustration of cyclic voltammetry measurements of carbon-supported platinum after preparation and after 4000 cycles of accelerated durability test.

### DETAILED DESCRIPTION

Provisions of the present disclosure are directed to palladium-platinum nanostructures, methods for producing palladium-platinum nanostructures and fuel cells that include palladium-platinum nanostructures. Generally, it has been found that palladium-platinum nanostructures that have been formed by depositing platinum on a palladium nanocrystal are characterized by a morphology that makes the structures ideal for use as a fuel cell electrocatalyst.

### Methods for Producing Dendritic Platinum Nanostructures

According to one embodiment of the present disclosure, dendritic platinum nanostructures are produced by contacting palladium nanocrystals with a platinum-containing compound. The platinum-containing compound may be reduced with a reducing agent such as ascorbic acid. By reducing the platinum-containing compound, platinum deposits on the palladium nanocrystal. The platinum generally forms platinum nanodendritic branches on the palladium crystal. In this regard, it should be understood that, as used herein, the terms “nanodendrite,” “branch” (including the phrase “nanodendritic branch”) and “arm” and generally synonymous and refer to structures (e.g., elongated structures) with a width less than about 100 nm or even less as described below. These terms may be used interchangeably and should not be considered in a limiting sense.

Without being bound to any particular theory, it is believed that the reducing agent causes platinum to deposit on discrete sites on the surface of the palladium nanocrystals. Platinum atoms and/or nanoparticles deposit preferentially on the initially deposited platinum nuclei and deposition proceeds along the developing platinum nanodendritic branch rather than uniformly on the palladium nanocrystal seed.

In one embodiment, the palladium nanocrystals used to seed the deposition of platinum are truncated octahedral in shape. In other embodiments, the nanocrystals are spherical, tetrahedral, octahedral, cubic, icosahedral or decahedral in shape and may have various degrees of truncation at the corners and/or edges.

Without departing from the scope of the present disclosure, palladium nanocrystals may be produced by any method known in the art. In one embodiment, the nanocrystals are prepared by contacting a palladium-containing compound with a reducing agent. Suitable palladium-containing compounds include, for example, palladium(II) chloride, palladium(II) bromide, palladium(II) nitrate, sodium tetrachloropalladate(II), potassium tetrachloropalladate(II), potassium hexachloropalladate(IV), ammonium tetrachloropalladate(II), ammonium hexachloropalladate(IV), palladium(II) acetate, palladium(II) acetylacetonate, palladium(II) hexafluoroacetylacetonate, palladium(II) trifluoroacetate, tetraamminepalladium(II) acetate, bis(acetonitrile)dichloropalladium(II), and bis(benzonitrile)palladium(II) chloride. In one embodiment, the palladium-containing compound is sodium tetrachloropalladate(II).

Suitable reducing agents include, for example, hydrogen, hydrazine, ascorbic acid, formic acid, tartaric acid, sodium borohydride, lithium aluminum hydride, citric acid, sodium citrate, ethylene glycol, diethylene glycol, tetraethylene glycol, polyethylene glycol, alcohol and poly(vinyl pyrrolidone). In one embodiment, the reducing agent is ascorbic acid. In one particular embodiment, the reducing agent is ascorbic acid and the palladium-containing compound is sodium tetrachloropalladate(II). Suitable solvents for forming the palladium nanocrystals may be polar or non-polar and aqueous or organic. In one embodiment, the solvent is water. Suitable organic solvents include, for example, ethanol, methanol, isopropanol, ethylene glycol, diethylene glycol, tetraethylene glycol, higher alcohols and ethers. The solvent may be degassed and the reaction may be conducted under air or under an inert atmosphere such as, for example, nitrogen, argon or helium.

The reaction solution may be maintained from about 20° C. to about 150° C. while the palladium nanocrystals are produced and, in other embodiments, the reaction solution is maintained from about 50° C. to about 150° C. or from about 75° C. to about 125° C.

In some embodiments, the molar ratio of reducing agent added to the reaction solution to palladium added to the reaction solution is as least about 1:1, at least about 1.2:1, at least about 1.3:1 or even at least about 1.5:1. In various embodiments, the molar ratio of reducing agent added to the reaction solution to palladium added to the reaction solution is from about 1:1 to about 3:1, from about 1.2:1 to about 3:1, from about 1.5:1 to about 3:1 or from about 1.5:1 to about 2:1.

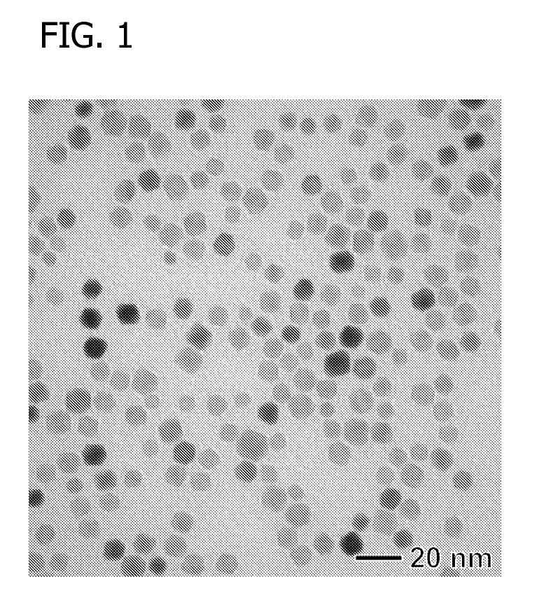

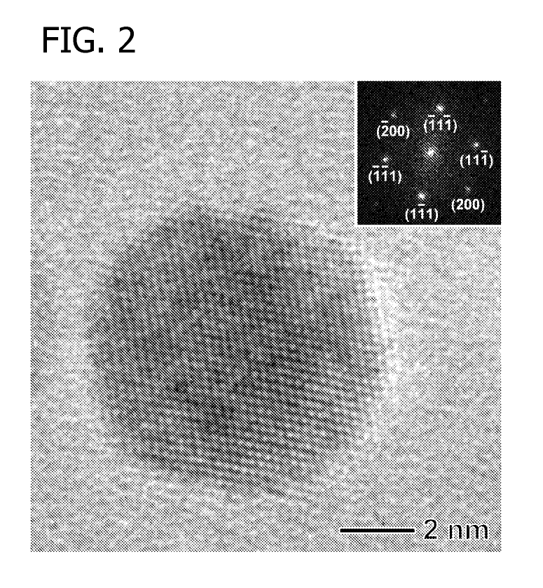

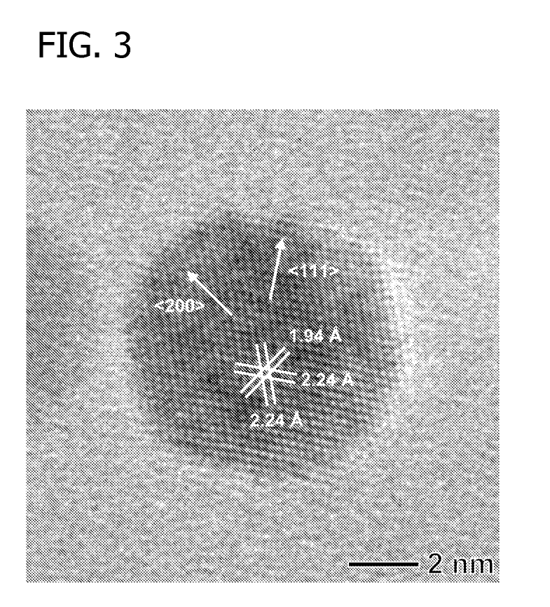

A transmission electron microscopy (TEM) image of truncated octahedral palladium nanocrystals produced by methods of embodiments of the present disclosure is shown in FIG. 1. A high-resolution TEM image of a single nanocrystal is shown in FIG. 2. The Fourier-transform (FT) pattern is inset in the Figure. As can be seen from the FT pattern, the crystal is enclosed by both {111} and {100} facets. In FIG. 3, the fringe orientation is shown which indicates that the truncated octahedron is encased by eight {111} and six {100} facets. The fringes show periods of 1.94 \acute{Å} and 2.24 \acute{Å} which agree with the {200} and {111} lattice spacing of face-centered cubic (fcc) palladium, respectively.

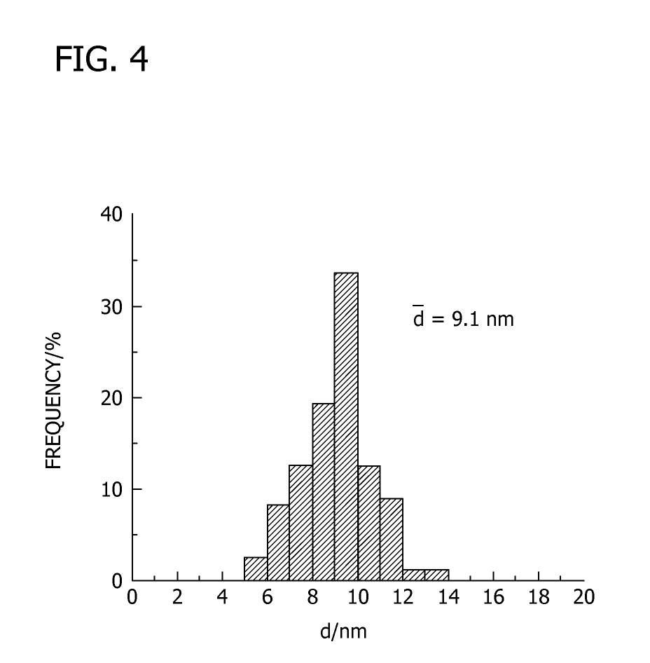

The average nominal diameter of the palladium nanocrystals may be less than about 15 nm and, in other embodiments, is less than about 10 nm. In other various embodiments, the average nominal diameter of the palladium nanocrystals is from about 5 nm to about 15 nm or even from about 7.5 nm to about 12.5 nm. Generally, the nominal diameter of the palladium nanocrystals ranges from about 4 nm to about 14 nm. The particle size distribution of truncated octahedral palladium nanocrystals prepared in accordance with the method of Example 1 is illustrated in FIG. 4. The average nominal diameter of the nanocrystals of Example 1 is about 9.1.

The palladium nanocrystals may be used as seeds for the formation of palladium-platinum nanostructures. Generally, the nanocrystals are contacted with a platinum-containing compound and a reducing agent is introduced to cause platinum to deposit on the nanocrystals. In one embodiment, the platinum-containing compound is selected from the group consisting of platinum(II) chloride, platinum(IV) chloride, platinum(II) bromide, chloroplatinic acid, sodium tetrachloroplatinate(II), sodium hexachloroplatinate(IV), potassium tetrachloroplatinate(II), potassium hexachloroplatinate(IV), tetraammineplatinum(II) chloride, tetraammineplatinum(II) nitrate, ammonium tetrachloroplatinate(II), ammonium hexachloroplatinate(IV) and platinum(II) acetylacetonate. In one embodiment, the platinum-containing compound is potassium tetrachloroplatinate(II).

Suitable reducing agents include, for example, hydrogen, hydrazine, ascorbic acid, formic acid, tartaric acid, sodium borohydride, lithium aluminum hydride, citric acid, sodium citrate, ethylene glycol, diethylene glycol, tetraethylene glycol, polyethylene glycol, alcohol and poly(vinyl pyrrolidone). In one embodiment, the reducing agent is ascorbic acid. In one particular embodiment, the reducing agent is ascorbic acid and the platinum-containing compound is potassium tetrachloroplatinate(II). Suitable solvents for producing the nanostructure may be polar or non-polar and aqueous or organic. In one embodiment, the solvent is water. Suitable organic solvents include, for example, ethanol, methanol, isopropanol, ethylene glycol, diethylene glycol, tetraethylene glycol, higher alcohols and ethers. The solvent may be degassed and the reaction may be conducted under air or under an inert atmosphere such as, for example, nitrogen, argon or helium.

The reaction solution may be maintained from about 20° C. to about 200° C. while the platinum nanodendritic branches are produced and, in other embodiments, the reaction solution is maintained from 40° C. to about 140° C. or from about 65° C. to about 115° C.

In some embodiments, the molar ratio of reducing agent added to the reaction solution to the amount of platinum added to the reaction solution is as least about 1:1, at least about 2:1, or even at least about 3:1. In various embodiments, the molar ratio of reducing agent added to the reaction solution to the platinum added to the reaction solution is from about 1:1 to about 10:1, from about 2:1 to about 10:1, from about 3:1 to about 10:1 or from about 3:1 to about 7:1.

The platinum-containing compounds may be added to the reaction solution containing the palladium nanocrystals continuously or may be added to the solution in one batch (i.e., added to the solution once). In some embodiments, the weight ratio of platinum added to the reaction solution containing the palladium nanocrystals to the palladium nanocrystals present in the reaction solution is at least about 3:2, at least about 3:1 or even at least about 4:1. In various embodiments, the weight ratio of platinum added to the reaction solution containing the palladium nanocrystals to the palladium nanocrystals present in the reaction solution is from about 3:2 to about 99:1, from about 3:2 to about 9:1, from about 3:1 to about 99:1 or even from about 3:1 to about 9:1.

Typically and in one embodiment, a matrix is not required to form the nanostructures of the present disclosure. In other embodiments, a matrix may be present in the reaction solution. Examples of matrices include micelles, vesicles, liposomes, sheets and meshes.

Platinum mass activity and stability may be improved through optimization of both the composition and the dimension of the palladium-platinum nanostructures by varying the ratio of platinum-containing compounds to palladium seeds involved in the synthesis (such as, for example, the synthesis of Example 2). Controlling the solution-phase synthesis may lead to next generation catalysts with substantial reduction in platinum loading while retaining high oxygen reduction activity. Durability may also be improved by incorporating gold into the catalyst. Gold may be incorporated as disclosed by Zhang et al. in Stabilization of Platinum Oxygen-Reduction Electrocatalysts Using Gold Clusters, Science 315, 220 (2007), which is incorporated herein for all relevant and consistent purposes.

### Palladium-Platinum Nanostructure Morphology

Nanostructures prepared by methods of embodiments of the present disclosure generally include palladium nanocrystals and platinum nanodendritic branches extending from the palladium nanocrystals. For purposes of the present disclosure, references to a “platinum nanostructure” are meant to include nanostructures which include atoms other than platinum, including, for example, palladium nanocrystal seeds.

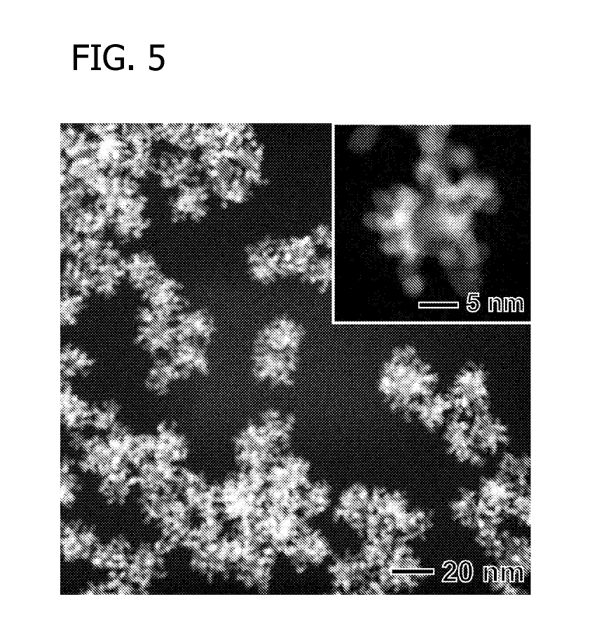

The nanostructures of embodiments of the present disclosure generally have a three-dimensional dendritic morphology. This is illustrated in FIG. 5 which is a high-angle annular dark-field scanning transmission electron microscopy (HAADF-STEM) image. As can be seen from FIG. 5, there is an intense contrast between the core and the surrounding branches of the nanostructure.

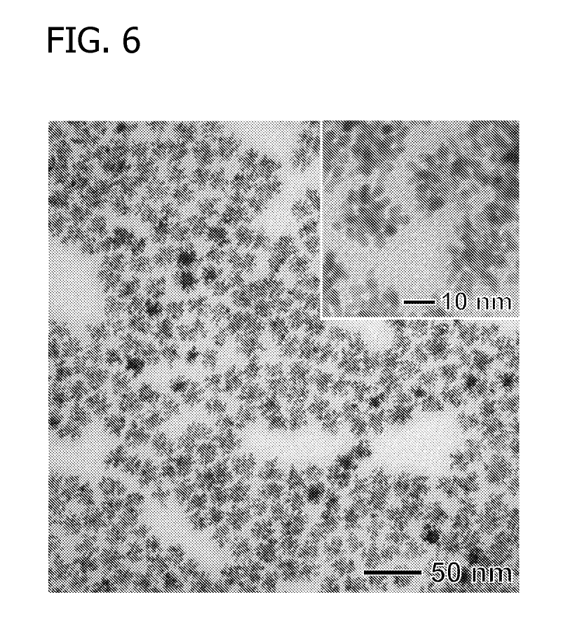

A TEM image of typical nanostructures is shown in FIG. 6. As can be seen from FIG. 6, several platinum nanodendritic branches extending from the palladium core have grown into dendritic tendrils. Single-arm branching can also be observed. Both the STEM image (FIG. 5) and the TEM image (FIG. 6) indicate an absence of isolated platinum nanoparticles in the product which indicates a high yield of platinum-palladium nanostructures.

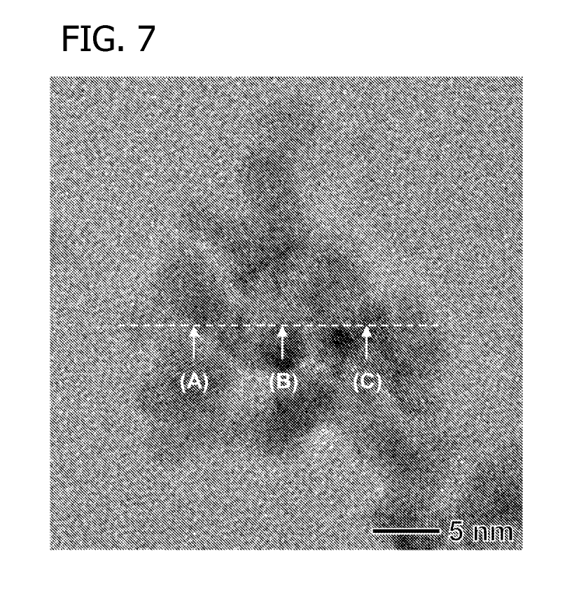

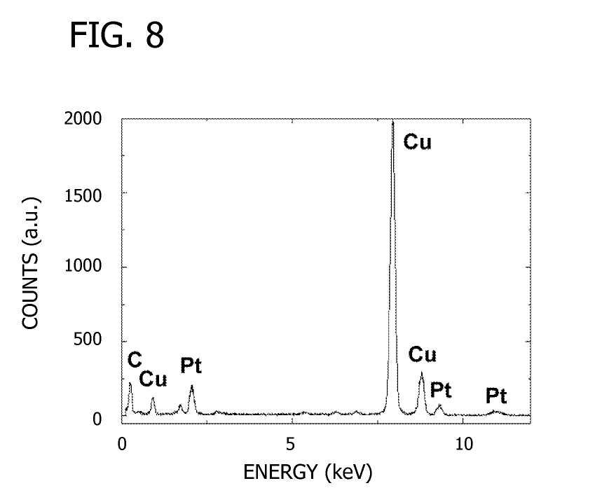

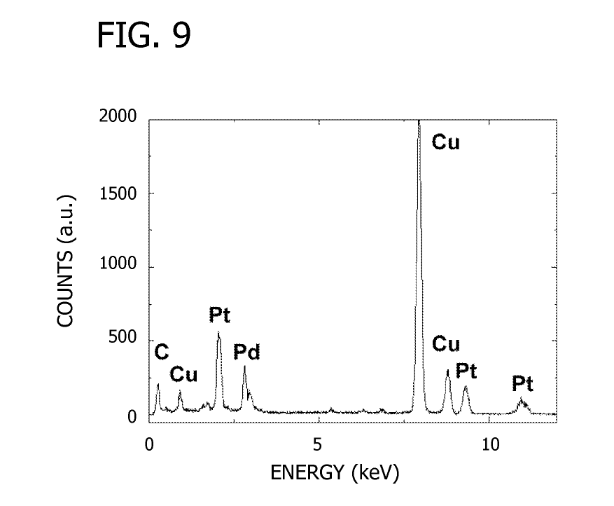

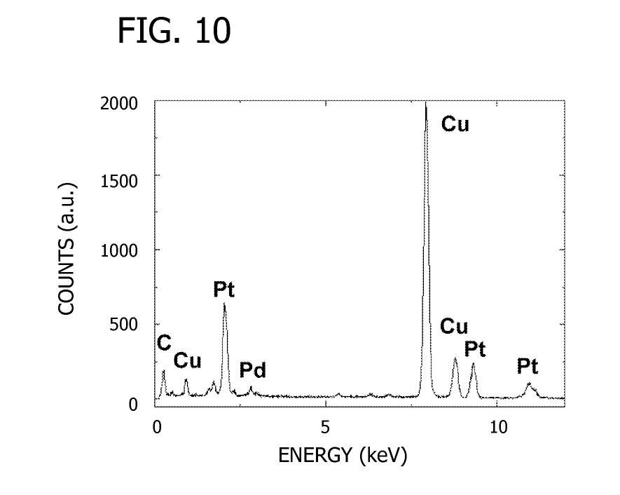

A high-resolution TEM image of a single nanostructure is shown in FIG. 7. Energy-dispersive X-ray spectroscopy (EDS) line scanning was performed at three sites (A, B, C). The EDS analysis is shown in FIGS. 8, 9 and 10, respectively. The analysis indicates that the core of the nanostructure is rich in palladium and the branches are rich in platinum.

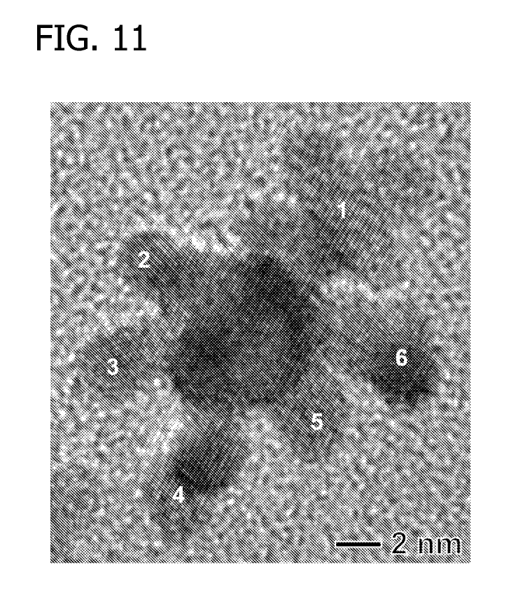

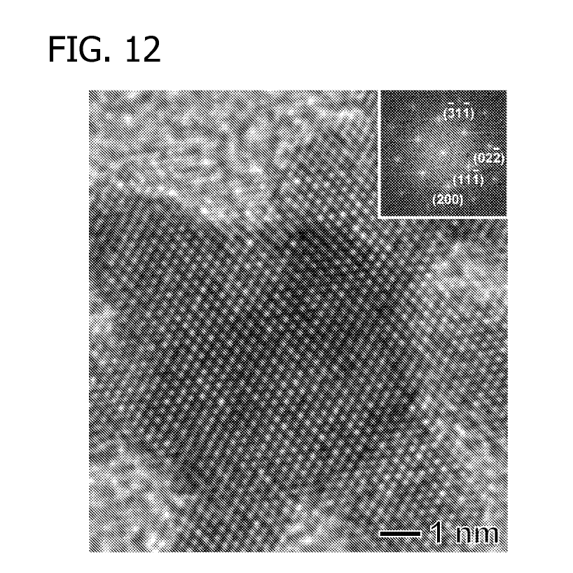

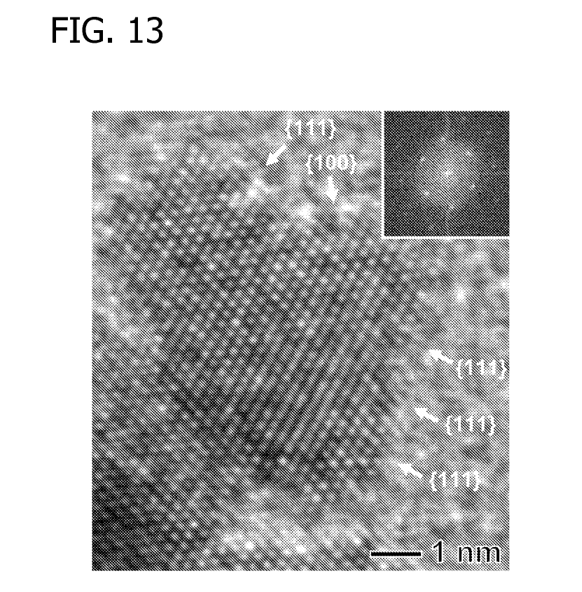

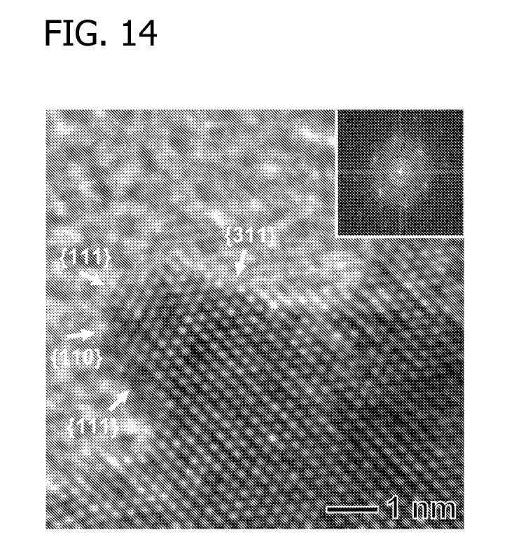

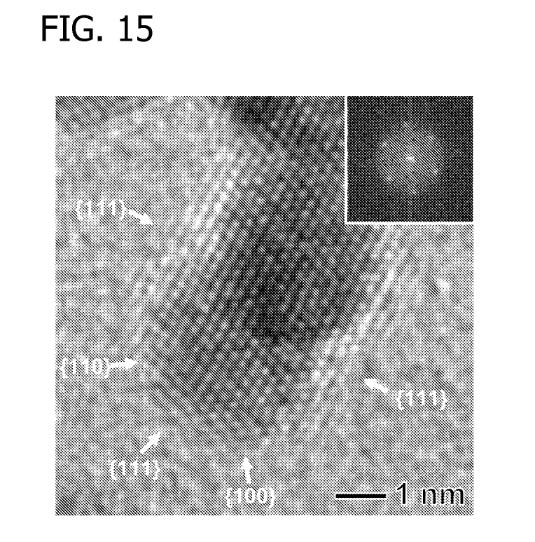

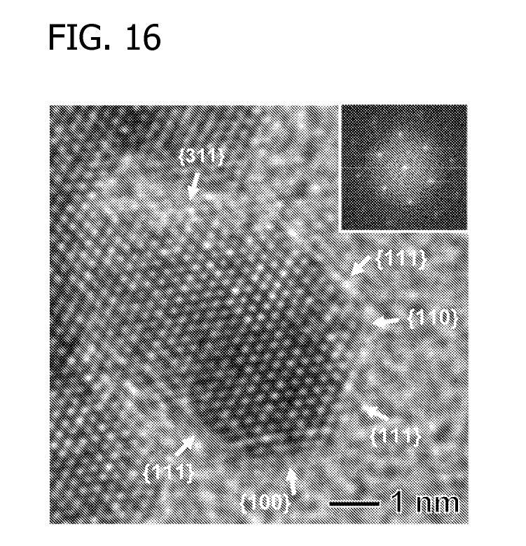

The nanodendritic platinum branches of nanostructures of embodiments of the present disclosure extend from multiple sites on the palladium nanocrystal. Further, the nucleation sites for platinum are distributed over the entire surface of the palladium nanocrystal and do not extensively overlap. These phenomena are illustrated in the HRTEM image of a single nanostructure prepared according to the process of Example 2 shown in FIG. 11. As can be seen from FIG. 11, the diameter of the branches is about 3 nm. An HRTEM image of the center of the nanostructure is shown in FIG. 12. The images illustrate how the continuous lattice fringes from the palladium core to the platinum branches. This is evidence of an epitaxial relation between palladium and platinum. HRTEM images of the branches labeled 1, 2, 4 and 6 in FIG. 11 are shown in FIGS. 13, 14, 15 and 16 with Fourier-transform (FT) patterns shown. These images reveal that most of the exposed facets on the platinum branches were {111} planes. Some {110} and high-index {311} facets can also be identified in addition to a small fraction of {100} facets. The identical FT patterns shown in the insets of the figures indicate that the platinum branches have the same lattice orientation as the palladium core regardless of their different growth directions.

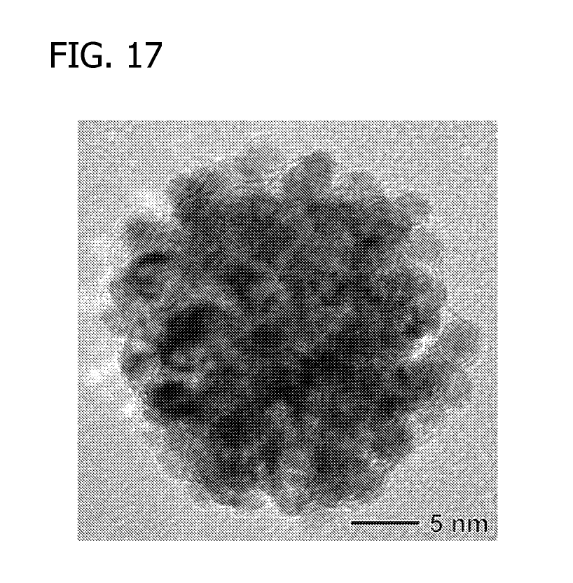

As discussed further above, the dendritic characteristics of the nanostructure may result from platinum depositing preferentially on the deposited platinum rather than on the palladium seed. While branching may occur without the use of palladium seeds, the resulting structure is characterized by a spherical, foam-like morphology with an overall size of from 20-35 nm. Such a structure is shown in FIG. 17. Truncated octahedral palladium seeds provide multiple nucleation sites for platinum deposition that are spatially separated from each other to avoid overlap and fusion to allow formation of platinum branches with an open, dendritic structure with relatively high surface area.

Generally, the nanostructures of the present disclosure have at least 2 nanodendritic platinum branches and, in other embodiments, at least about 3, at least about 5 or even at least about 8 nanodendritic platinum branches. The average nominal diameter of the platinum nanodendritic branches of nanostructures of embodiments of the present disclosure is typically from about 1 nm to about 8 nm and, in other embodiments from about 2 nm to about 6 nm.

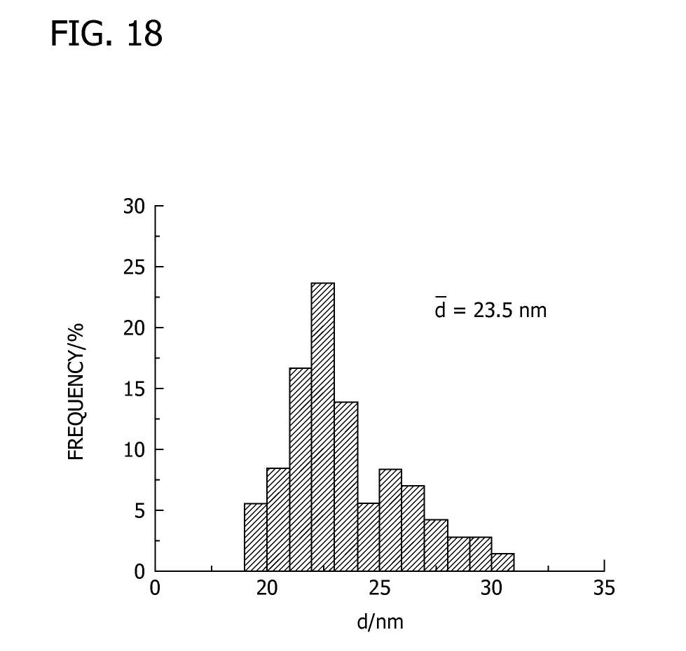

The average nominal diameter of the nanostructures may be at least about 15 nm and, in another embodiment, is at least about 20 nm. In some embodiments, the average nominal diameter of the nanostructures is less than about 50 nm and even less than about 30 nm. In various embodiments, the average nominal diameter of the nanostructures may be from about 15 nm to about 50 nm, from about 15 nm to about 30 nm or from about 20 nm to about 30 nm. The particle size distribution of nanostructures prepared in accordance with the method of Example 2 is illustrated in FIG. 18. The average nominal diameter of the nanostructures of Example 2 is about 23.5 nm.

In various embodiments, the weight percentage of platinum in the nanostructure is at least about 60%, at least about 75% or even at least about 80%. In some embodiments, the weight percentage of platinum is from about 60% to about 99%, from about 60% to about 90%, from about 75% to about 99% or from about 75% to about 90%.

The specific electrochemically active surface area (specific ECSA) of the palladium-seeded, dendritic platinum nanostructures may be at least about 35 m² per gram of palladium and platinum in the structure and, in another embodiment, at least about 45 m² per gram of palladium and platinum in the structure. In other embodiments, the specific ECSA of the nanostructures is from about 35 to 55 m² per gram of palladium and platinum in the structure or from about 45 to about 50 m² per gram of palladium and platinum in the structure.

The mass activity at 0.9 V and room temperature versus RHE of palladium-seeded, dendritic platinum nanostructures may be at least about 0.13 mA per μg of platinum in the structure and, in other embodiments, at least about 0.15, at least about 0.17, at least 0.20 or even at least about 0.23 mA per μg of platinum in the structure. In some embodiments, the mass activity at 0.9 V versus RHE is from about 0.13 to about mA per μg of platinum in the structure and, in other embodiments is from about 0.15 to about 0.3 or from about 0.2 to about 0.3 mA per μg platinum in the structure.

### Fuel Cell Incorporating Dendritic Platinum Nanostructures

The palladium-platinum nanostructures described above may be incorporated into an electrode of a fuel cell to improve the performance of the fuel cell. Generally, the fuel cell will include a first electrode, a second electrode and an electrolyte between the first electrode and the second electrode. The first electrode comprises palladium-platinum nanostructures comprising palladium nanocrystals and platinum nanodendritic branches extending from the palladium nanocrystals. In some embodiments, the second electrode also comprises the palladium-platinum nanostructures.

The electrolyte of the fuel cell many be a solid polymer membrane. Suitable polymer membranes include the commercially available copolymers of tetrafluoroethylene and perfluorinated vinyl ethers derivatized with acidic groups, such as sulfonic, carboxylic, phosphinic, or boric acid groups. Suitable membranes include, for example, NAFION® membranes (Du Pont), FLEMION® membranes (Asahi Glass), ACIPLEX™ membranes (Asahi Kasei Chemicals), and DOW membranes (Dow Chemical).

The specific electrochemically active surface area (specific ECSA) of electrodes incorporating the palladium-platinum nanostructures may be at least about 35 m² per gram of palladium and platinum in the electrode and, in another embodiment, at least about 45 m² per gram of palladium and platinum in the electrode. In other embodiments, the specific ECSA of an electrode that incorporates the palladium-platinum nanostructure is from about 35 to 55 m² per gram of palladium and platinum in the electrode or from about 45 to about 50 m² per gram of palladium and platinum in the electrode.

The mass activity at 0.9 V versus RHE of electrodes that include palladium-seeded, dendritic platinum nanostructures therein may be at least about 0.13 mA per μg of platinum in the electrode and, in other embodiments, at least about 0.15, at least about 0.17, at least about 0.20 or even at least about 0.23 mA per μg of platinum in the electrode. In some embodiments, the mass activity at 0.9 V versus RHE is from about 0.13 to about 0.30 mA per μg of platinum in the electrode and, in other embodiments, is from about 0.15 to about 0.30 or from about 0.20 to about 0.30 mA per μg of platinum in the electrode.

### EXAMPLES

### Example 1

### Production of Truncated Octahedral Palladium Nanocrystals

Poly(vinyl pyrrolidone) (PVP, 105 mg, MW=55,000, Aldrich), L-ascorbic acid (60 mg, Aldrich), and citric acid (60 mg, Fisher) were dissolved in deionized water (8 mL) hosted in a 25-mL, three-necked flask (equipped with a reflux condenser and a Teflon-coated magnetic stirring bar) and heated to 100° C. in air under magnetic stirring. Meanwhile, Na₂PdCl₄ (57 mg, Aldrich) was dissolved at room temperature in distilled water (3 mL). The aqueous solution of Na₂PdCl₄ was then rapidly injected into the flask by pipette. The reaction mixture was heated at 100° C. in air for 3 hours, and then cooled down to room temperature.

### Example 2

### Production of Palladium-Platinum Nanostructures

The suspension of palladium nanocrystals of Example 1 and aqueous solution (6 ml) of PVP (35 mg) and L-ascorbic acid (60 mg) were added into a 25-mL, three-necked flask. The mixture was heated to 90° C. in air under magnetic stirring. K₂PtCl₄ (27 mg, Aldrich) was dissolved at room temperature in distilled water (3 mL). The aqueous solution of K₂PtCl₄ was then rapidly injected into the flask by pipette. The reaction mixture was heated at 90° C. in air for 3 hours, and then cooled down to room temperature. The product was collected by centrifugation and washed several times with water for further use in characterization and electrochemical measurements.

### Example 3

### Structural Imaging

Transmission electron microscopy (TEM) images were taken of the palladium nanocrystals of Example 1 (FIG. 1), of the palladium-platinum nanostructures of Example 2 (FIG. 6) and non-seeded platinum nanostructures (FIG. 17). The images were captured using a Phillips 420 microscope operated at 120 kV.

High-resolution TEM (HRTEM) images were taken of a palladium nanocrystal of Example 1 (FIG. 2) and palladium-platinum nanostructures of Example 2 (FIGS. 7, 11-16). The images were taken on a JEOL 2010F microscope operating at 200 kV.

A high-angle annular dark-field scanning transmission electron microscopy (HAADF-STEM) image was taken of the nanostructures of Example 2 (FIG. 5). The image was recorded with a Hitachi HD-2700 microscope.

The composition of the palladium-platinum nanostructures of Example 2 was determined by inductively coupled plasma mass spectrometry (ICP-MS 7500CS, Agilent Technologies). The overall weight percentage of platinum in the nanostructures was about 85%.

### Example 4

### Comparison of the Electrochemically Active Surface Area of Palladium-Seeded, Dendritic Platinum Nanostructures, Carbon-Supported Platinum and Platinum Black

Electrochemical measurements were performed at room temperature using a glassy carbon rotating disk electrode (RDE, Pine Research Instrumentation) connected to a PARSTAT 283 potentialstat (Princeton Applied Research). A leak-free AgCI/Ag/KC1(3 M) electrode (Warner Instrument) was used as the reference. All potentials were converted to reversible hydrogen electrode (RHE). The counter electrode was a platinum mesh (1×1 cm²) attached to a platinum wire. The electrolyte was 0.1 M perchloric acid diluted from 70% (Baker, ACS Reagent grade) using Millipore ultrapure water.

Several electrodes were prepared for comparison purposes. One electrode included carbon-supported platinum; one included platinum black and another included the palladium-platinum nanostructures of Example 2. For the carbon-supported platinum catalyst (20 wt %; 3.2 nm platinum nanoparticles on Vulcan XC-72 carbon support; E-TEK), an aqueous dispersion (1 mg/mL) was prepared and sonicated for 5 min. Fifteen microliters of the dispersion was then transferred onto the glassy carbon RDE (0.196 cm²). For the palladium-seeded, dendritic platinum catalyst, the sample was diluted to 0.15 mg/mL (based on ICP-MS measurement) and 20 μL of the dispersion was transferred onto the RDE. Therefore, the metal loading for the palladium-platinum catalyst and the carbon-supported platinum catalyst was 3 μg (i.e., 15.3 μg/cm² based on the geometric electrode area). For platinum black (Aldrich, fuel grade), the working electrode was prepared using the same procedure except that the loading amount of metal was 8 μg (i.e., 40.8 μg/cm² based on the geometric electrode area). Upon drying in air for 2 hours, the electrode was covered with 15 μL of 0.05 wt % Nafion solution. After evaporation of water, the electrode was put under vacuum for 30 minutes before measurement.

The three electrodes were subjected to cyclic voltammetry (CV) in 0.1 M HClO₄ solution under flow of argon (Airgas, ultrahigh purity) at a sweep rate of 50 mV/s. The electrochemically active surface area (ECSA) was estimated by integrating the charge associated with H_{upd} adsorption (Q_{H}) between 0 and 0.37 V after double-layer correction using 210 μC/cm² for monolayer adsorption of hydrogen on a Pt surface (q_{H}). The H_{upd} adsorption charge (Q_{H}) can be determined using Q_{H}=0.5×Q, where Q is the charges in the H_{upd} adsorption/desorption area obtained after double-layer correction.

The specific ECSA was calculated based on the following Equation (1):

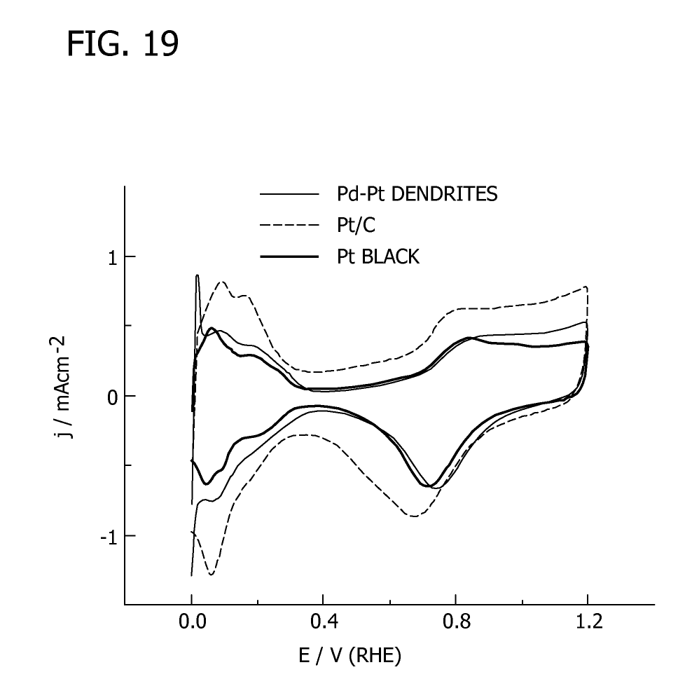

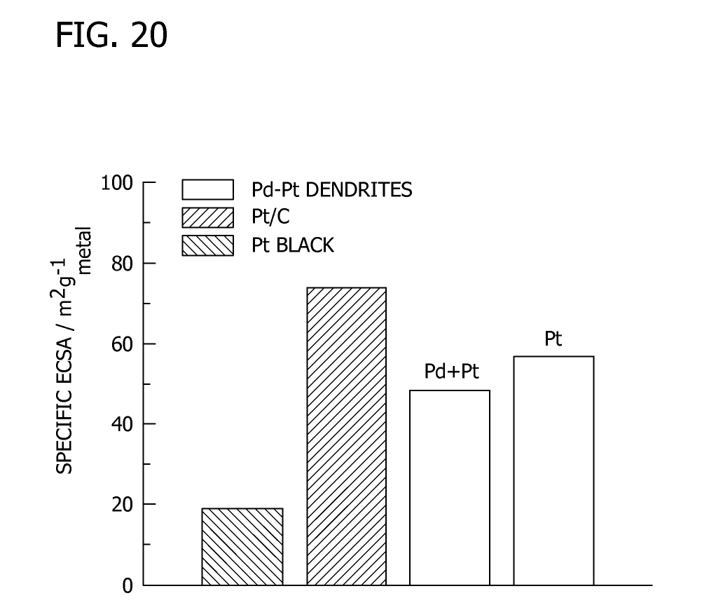

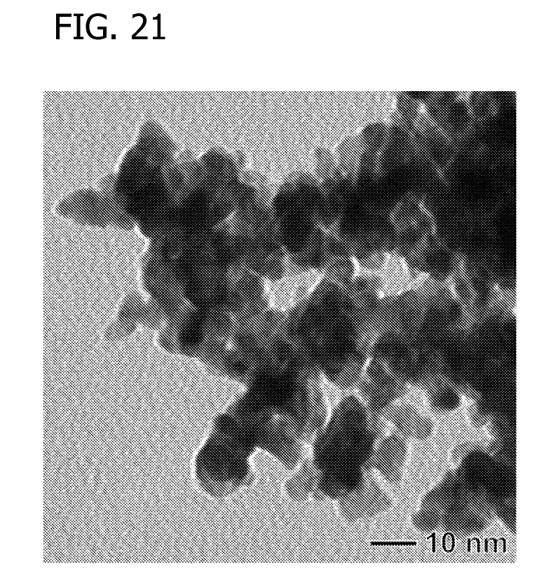

specific ECSA=Q_{H}/(m×q_{H}) (1)

wherein Q_{H} is the charge for H_{upd} adsorption, m is the loading amount of metal, and q_{H} is the charge required for monolayer adsorption of hydrogen on a platinum surface. The CV curves for the electrodes of the three catalysts are shown in FIG. 19. The CV curves exhibited two distinctive potential regions associated with H_{upd} adsorption/desorption processes (H⁺+e⁻=H_{upd}) between 0<E<0.37 V and the formation of a OH_{ad} layer (2H₂O=OH_{ad}+H_{ad}+H₃O⁺+e⁻) beyond ˜0.6 V, where H_{upd} and OH_{ad} refer to the underpotentially deposited hydrogen and the adsorbed hydroxyl species, respectively. As shown in FIG. 20, the specific ECSA (i.e., ECSA per unit weight of metal) of the palladium-platinum nanostructure catalyst (48.5 m²/g_{pd+pt}) was found to be 66% of the carbon-supported platinum catalyst (74.0 m²/gₚₜ). Based on the platinum mass of the palladium-seeded, dendritic platinum nanostructure, the specific ECSA (57.1 m²/gₚₜ) was 77% of the carbon-supported platinum catalyst. In contrast, platinum black exhibited a very small specific ECSA (19.1 m²/gₚₜ) mainly because of extensive agglomeration in the sample. This agglomeration may be seen in the TEM image of the catalyst shown in FIG. 21. The highly branched structure of the platinum nanostructures provides a reasonably high surface area despite their relatively large overall particle size.

### Example 5

### Comparison of the Polarization Curves of Palladium-Seeded Dendritic Platinum Nanostructures, Carbon-Supported Platinum and Platinum Black for the Oxygen Reduction Reaction

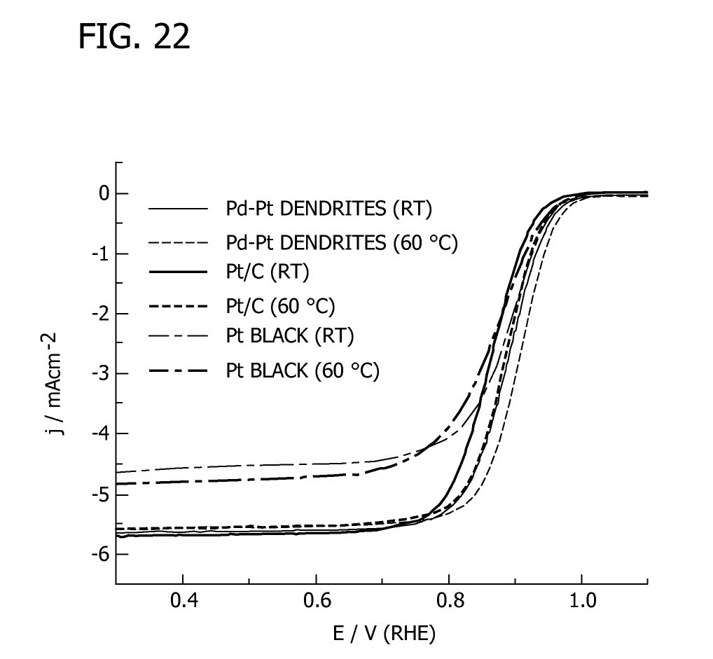

FIG. 22 shows polarization curves for oxygen reduction by the three electrodes of Example 4 in oxygen saturated 0.1 M HClO₄ solutions obtained using a rotating disk electrode at room temperature, 1600 rpm and at a sweep rate of 10 mV/S. In order to produce a clean electrode surface, several potential sweeps between −0.05 and 1.3 V verses the reversible hydrogen electrode (RHE) were applied to the electrode prior to oxygen reduction activity measurement. In the oxygen reduction polarization curve, current densities were normalized in reference to the geometrical area of the glassy carbon RDE (0.196 cm²).

For the oxygen reduction reaction at a RDE, the Koutecky-Levich equation can be utilized as shown in Equation (2) below:

$$\frac{1}{i} = \frac{1}{{i}_{k}} + \frac{1}{{i}_{d}} \qquad ( 2 )$$

wherein i is the experimentally measured current, i_{d} is the diffusion-limiting current, and iₖ is the kinetic current. The kinetic current may be calculated based on the following Equation (3):

$${i}_{k} = \frac{i \times {i}_{d}}{{i}_{d} - i} \qquad ( 3 )$$

For each catalyst, the kinetic current was normalized for the loading amount of metal and ECSA in order to obtain mass and specific activities, respectively.

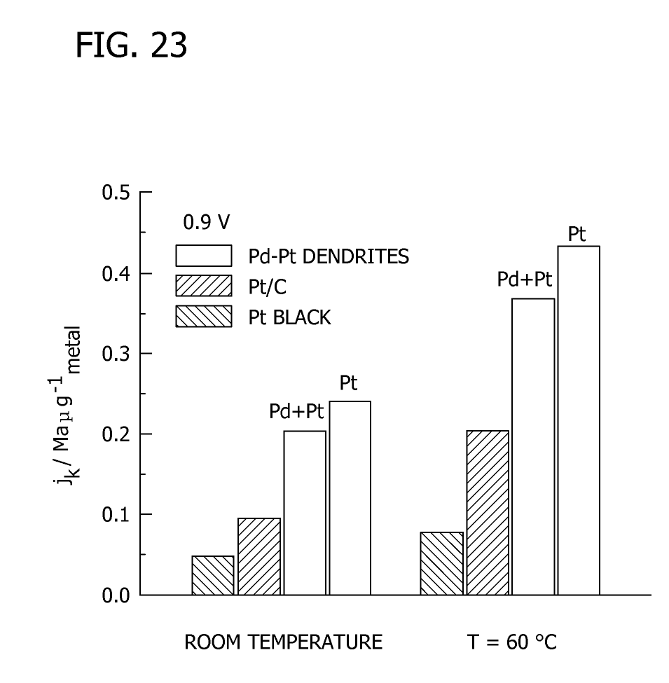

For the palladium-seeded, dendritic platinum nanostructure and the carbon-supported platinum catalyst, the metal loading on the RDE was 15.3 μg/cm². The loading was increased to 40.8 μg/cm² for the platinum black catalyst to avoid significant drop of the diffusion-limiting currents that occurs at relatively low loadings for low specific surface area catalysts. Polarization curves are shown in FIG. 22. For all three catalysts, the diffusion-limiting currents were obtained in the potential region below 0.6 V, whereas a mixed kinetic-diffusion control region occurs between 0.7 and 1.0 V. The kinetic current was calculated from the oxygen reduction reaction polarization curve by using mass-transport correction and normalized to the loading amount of metal in order to compare the mass activity of different catalysts. As can be seen from FIG. 23, at room temperature, based on the total mass of palladium and platinum, the palladium-seeded, dendritic platinum nanostructures exhibited a mass activity of 0.204 mA/μg_{Pd+Pt} at 0.9 V versus RHE, which was 2.1 and 4.3 times greater than that of carbon-supported platinum (0.095 mA/μgₚₜ) and platinum black (0.048 mA/μgₚₜ), respectively.

As shown in FIG. 23, if the platinum mass was solely taken into account, the mass activity of the palladium-platinum nanostructures (0.241 mA/μgₚₜ) was 2.5 times greater than that of the carbon-supported catalyst and 5.0 times greater than the platinum black catalyst. At 60° C., the palladium-seeded, dendritic platinum catalyst exhibited a platinum mass activity (0.433 mA/μgₚₜ) greater than that of the carbon-supported catalyst (0.204 mA/μgₚₜ) and the platinum black (0.078 mA/μgₚₜ).

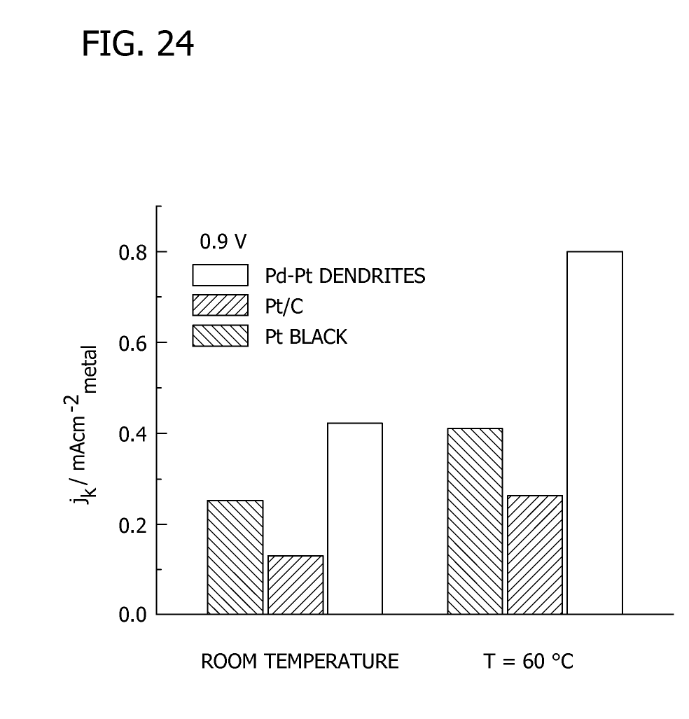

In order to better understand the observed difference in oxygen reduction reaction activity, the kinetic current was normalized against the ECSA of each catalyst. As shown in FIG. 24 and Table 1 below, depending on the temperature, the dendritic platinum nanostructures had a specific activity (i.e., kinetic current per unit surface area of catalyst) of 3.1 to 3.4 times that of the carbon-supported and 1.7 to 2.0 times that of the platinum black catalyst. U.S. Department of 2015 targets at 80° C. are also shown in Table. 1. This data further evinces accelerated oxygen reduction reaction kinetics on the surface of palladium-seeded, dendritic platinum nanostructures.

TABLE 1
Surface areas and ORR activities at 0.9 V versus RHE for Pd—Pt nanostructures and commercial Pt catalysts

| | Catalyst | Specific | Specific activity | Mass activity | Specific activity | Mass activity |
|---|---|---|---|---|---|---|
| | loading | ECSA | at RT | at RT | at 60° C. | at 60° C. |
| Catalyst | (μgₘₑₜₐₗ/cm²_{disk}) | (m²/gₘₑₜₐₗ) | (mA/cm²ₘₑₜₐₗ) | (mA/μgₘₑₜₐₗ) | (mA/cm²ₘₑₜₐₗ) | (mA/μgₘₑₜₐₗ) |
| Pd-Seeded Dendritic | 15.3 | 48.5 ± 5.9^{†} | 0.424 ± 0.032 | 0.204 ± 0.011^{†} | 0.802 ± 0.045 | 0.368 ± 0.024^{†} |
| Pt Nanostructures | | (57.1 ± 6.9)^{‡} | | (0.241 ± 0.013)^{‡} | | (0.433 ± 0.028)^{‡} |
| 20% Pt/C | 15.3 | 74.0 ± 5.1 | 0.130 ± 0.006 | 0.095 ± 0.008 | 0.262 | 0.204 |
| (E-TEK) | | | | | | |
| Pt black (Aldrich, | 40.8 | 19.1 | 0.252 | 0.048 | 0.411 | 0.078 |
| fuel cell grade) | | | | | | |
| DOE Targets | | | | | 0.720 | 0.440 |

(^{†}Per unit weight of metals including both Pd and Pt;
^{‡}Per unit weight of Pt).

The order of increasing oxidation reduction reaction activity of low-index crystallographic facets of platinum in a non-absorbing electrolyte such as perchloric acid is known to be Pt(100)<<Pt(1 11)<Pt(110), with the difference in activity between Pt(111) and Pt(110) being minor. This difference in ORR activity most likely arises from the structure-sensitive inhibiting effect of OH_{ad} species on Pt(hkl), which blocks the active site for oxygen adsorption and thus retards the oxygen reduction kinetics. In addition, the high-index, stepped platinum surfaces have exhibited slightly greater oxygen reduction activities than the low-index planes in acidic solutions, which could be attributed to the favorable adsorption of oxygen molecules on the stepped surfaces. Without being bound to any particular theory, the higher specific activity of the palladium-seeded, dendritic platinum nanostructures might be related to the preferential exposure of {111} facets along with some {110} and high-index {311} facets on platinum branches as compared to small platinum nanoparticles on the carbon-supported platinum catalyst, which usually take the shape of a truncated octahedron and are thus enclosed by a mix of {100} and {111} facet. As expected, the platinum black samples showed an irregular morphology with poorly defined facets. Thus the observed high activity based on platinum mass for the palladium-seeded, dendritic platinum nanostructures may result from the reasonably high surface area intrinsic to the dendritic morphology and the exposure of particularly active facets.

### Example 6

### Durability Comparison Between Palladium-Seeded, Dendritic Platinum Nanostructures, Carbon-Supported Platinum and Platinum Black

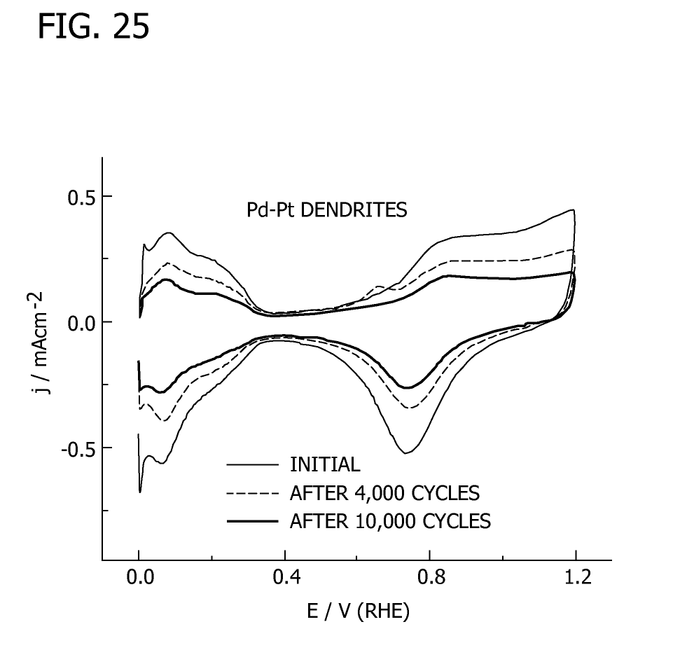

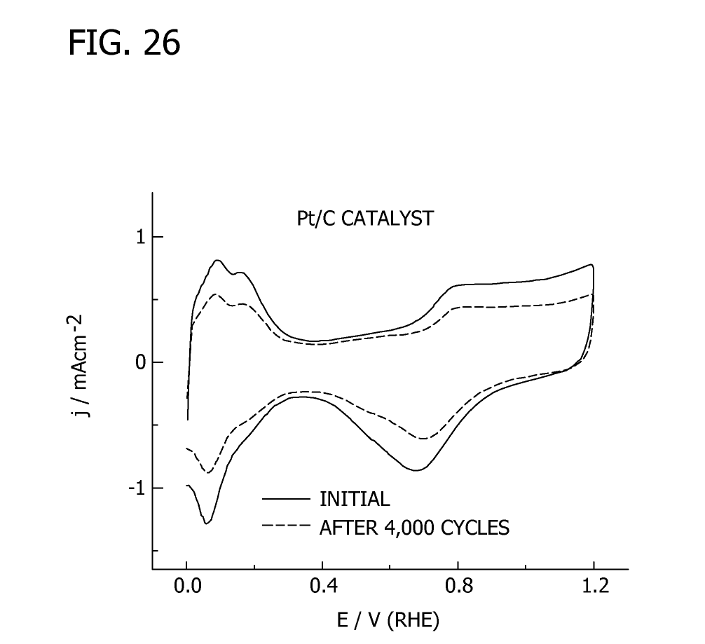

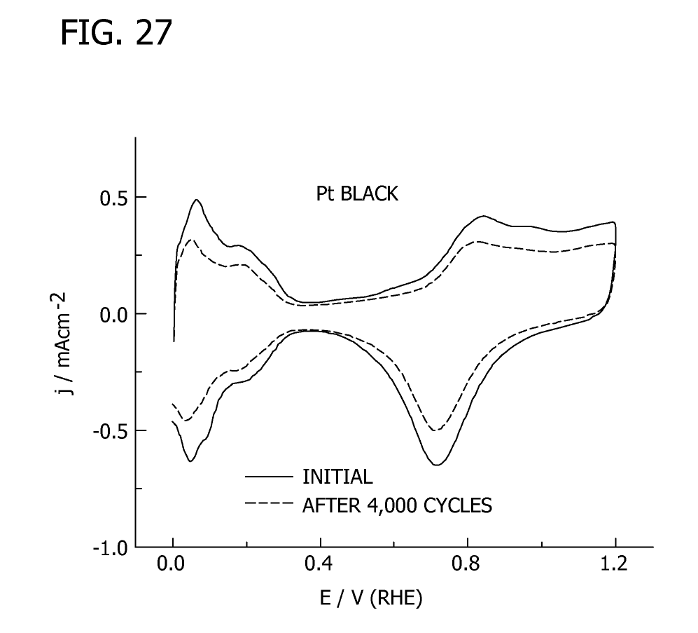

Accelerated durability tests were performed by applying linear potential sweeps between 0.6 and 1.1 V verses RHE at 50 mV/s in oxygen saturated 0.1 M HCl O₄ solutions at room temperature. After 4,000 cycles, the CV measurements showed a loss of 30% in ECSA for the palladium-seeded, dendritic platinum nanostructures (FIG. 25), 36% for the carbon-supported platinum catalyst (FIG. 26), and 33% for the platinum black catalyst (FIG. 27). This suggests that the palladium-platinum nanostructures are characterized by durability slightly better than the carbon-supported platinum catalyst and the platinum black catalyst. After 10,000 cycles, the palladium-seeded dendritic platinum nanostructures showed a loss of 50% in ECSA. Platinum mass activity and stability may possibly be improved through methods described above.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above apparatus and methods without departing from the scope of the disclosure, it is intended that all matter contained in the above description and shown in the accompanying figures shall be interpreted as illustrative and not in a limiting sense.

1. A method of producing a palladium-platinum nanostructure, the method comprising
contacting palladium nanocrystals with a platinum-containing compound; and
reducing the platinum-containing compound with a reducing agent to cause platinum to deposit on the palladium nanocrystal and form platinum nanodendritic branches.

2. A method as set forth in claim 1 wherein the palladium nanocrystals are characterized by a truncated octahedral shape.

3. A method as set forth in claim 1 wherein the palladium nanocrystals are characterized by shape selected from the group consisting of spherical, tetrahedral, octahedral, cubic, truncated cubic, icosahedral and decahedral.

4. A method as set forth in claim 1 wherein the platinum-containing compound is selected from the group consisting of platinum(II) chloride, platinum(IV) chloride, platinum(II) bromide, chloroplatinic acid, sodium tetrachloroplatinate(II), sodium hexachloroplatinate(IV), potassium tetrachloroplatinate(II), potassium hexachloroplatinate(IV), tetraammineplatinum(II) chloride, tetraammineplatinum(II) nitrate, ammonium tetrachloroplatinate(II), ammonium hexachloroplatinate(IV) and platinum(II) acetylacetonate.

5. A method as set forth in claim 1 wherein the reducing agent is selected from the group consisting of hydrogen, hydrazine, ascorbic acid, formic acid, tartaric acid, sodium borohydride, lithium aluminum hydride, citric acid, sodium citrate, ethylene glycol, diethylene glycol, tetraethylene glycol, polyethylene glycol, alcohol and poly(vinyl pyrrolidone).

6. A method as set forth in claim 1 wherein the reducing agent is ascorbic acid.

7. A method as set forth in claim 1 wherein the reducing agent causes platinum to deposit on discrete sites on the surface of the palladium nanocrystal and form nanodendritic branches.

8. A method as set forth in claim 1 wherein the palladium nanocrystals are formed by reducing a palladium-containing compound with a reducing agent.

9. A method as set forth in claim 8 wherein the palladium-containing compound is selected from the group consisting of palladium(II) chloride, palladium(II) bromide, palladium(II) nitrate, sodium tetrachloropalladate(II), potassium tetrachloropalladate(II), potassium hexachloropalladate(IV), ammonium tetrachloropalladate(II), ammonium hexachloropalladate(IV), palladium(II) acetate, palladium(II) acetylacetonate, palladium(II) hexafluoroacetylacetonate, palladium(II) trifluoroacetate, tetraamminepalladium(II) acetate, bis(acetonitrile)dichloropalladium(II), and bis(benzonitrile)palladium(II) chloride.

10. A method as set forth in claim 9 wherein the reducing agent is selected from the group consisting of hydrogen, hydrazine, ascorbic acid, formic acid, tartaric acid, sodium borohydride, lithium aluminum hydride, citric acid, sodium citrate, ethylene glycol, diethylene glycol, tetraethylene glycol, polyethylene glycol, alcohol and poly(vinyl pyrrolidone).

11. A palladium-platinum nanostructure comprising a palladium nanocrystal and a platinum nanodendritic branches extending from the palladium nanocrystal.

12. A palladium-platinum nanostructure as set forth in claim 11 wherein the palladium nanocrystal is characterized by a truncated octahedral shape.

13. A palladium-platinum nanostructure as set forth in claim 11 wherein the weight percentage of platinum in the nanostructure is from about 60% to about 99%.

14. A palladium-platinum nanostructure as set forth in claim 11 wherein at least two platinum nanodendritic branches extend from the palladium nanocrystal.

15. A palladium-platinum nanostructure as set forth in claim 11 wherein at least three platinum nanodendritic branches extend from the palladium nanocrystal.

16. A palladium-platinum nanostructure as set forth in claim 11 wherein the platinum nanodendritic branch has an average nominal diameter of from about 1 nm to about 8 nm.

17. A fuel cell comprising a first electrode, a second electrode and an electrolyte between the first electrode and the second electrode, wherein the first electrode comprises palladium-platinum nanostructures comprising palladium nanocrystals and platinum nanodendritic branches extending from the palladium nanocrystals.

18. A fuel cell as set forth in claim 17 wherein the platinum-palladium nanocrystals have a truncated octahedral shape.

19. A fuel cell as set forth in claim 17 wherein the first electrode has a mass activity at 0.9 V at room temperature verses RHE of at least 0.13 mA per μg of platinum and palladium in the electrode.

20. A fuel cell as set forth in claim 17 wherein the first electrode has a specific electrochemically active surface area of at least about 35 m² per gram of palladium and platinum in the electrode.
